(19) United States
(12) Patent Application Publication
(10) Pub. No.: US 2026/0121631 A1
(43) Pub. Date: Apr. 30, 2026

(54) GATE DRIVING CIRCUIT

(71) Applicant: InnoCare Optoelectronics Corporation, Tainan City (TW)

(72) Inventors: Pin-Chung Chen, Tainan City (TW); Chin-Chi Chen, Tainan City (TW)

(73) Assignee: InnoCare Optoelectronics Corporation, Tainan City (TW)

(21) Appl. No.: 19/337,842

(22) Filed: Sep. 23, 2025

(30) Foreign Application Priority Data
Oct. 24, 2024 (TW) 113140511

(51) Int. Cl. H03K 17/16; H03K 17/284

(52) U.S. Cl. CPC H03K 17/162; H03K 17/284

(57) ABSTRACT

A gate driving circuit is provided. The gate driving circuit includes an output transistor, a first discharge transistor, and a second discharge transistor. A first terminal of the output transistor receives an operating clock. A control terminal of the output transistor is connected to a control node. The output transistor outputs an n-th stage gate driving signal through a second terminal of the output transistor. The first discharge transistor discharges a voltage value located at the control node in a first time interval. The second discharge transistor discharges the voltage value located at the control node in a second time interval. The second time interval is different from the first time interval.

### CROSS-REFERENCE TO RELATED APPLICATION

This application claims the priority benefit of Taiwan application serial no. 113140511, filed on October 24, 2024. The entirety of the above-mentioned patent application is hereby incorporated by reference herein and made a part of this specification.

### BACKGROUND

### Technical Field

The disclosure relates to an electronic circuit, and more particularly, to a gate driving circuit.

### Description of Related Art

A gate driving device used in a display device includes a multi-stage gate driving circuit. The gate driving circuit may generate a gate driving signal according to an operating clock and a previous stage gate driving signal. It should be noted that the operating clock and the previous stage gate driving signal may include noise. Once the gate driving signal is affected by the noise such that the gate driving signal becomes abnormal, an output of a next stage gate driving circuit will also become abnormal. The noise is transmitted and accumulated to the next stage gate driving circuit. Therefore, operating stability of the gate driving device is reduced.

### SUMMARY

The disclosure provides a gate driving circuit that may improve operating stability of a gate driving device.

In an embodiment of the disclosure, a gate driving circuit includes an output transistor, a first discharge transistor, and a second discharge transistor. A first terminal of the output transistor receives an operating clock. A control terminal of the output transistor is connected to a control node. The output transistor generates an n-th stage gate driving signal according to a voltage value of the control node and the operating clock, and outputs the n-th stage gate driving signal through a second terminal of the output transistor. The first discharge transistor is connected to the control node. The first discharge transistor discharges the voltage value located at the control node in a first time interval. The second discharge transistor is connected to the control node. The second discharge transistor discharges the voltage value located at the control node in a second time interval. The second time interval is different from the first time interval, and n is a positive integer.

Based on the above, the first discharge transistor discharges the voltage value located at the control node in the first time interval. The second discharge transistor discharges the voltage value located at the control node in the second time interval. The second time interval is different from the first time interval. Therefore, the voltage value located at the control node is not susceptible to the interference noise. In this way, the risk of the abnormal output of the gate driving circuit is reduced. The operating stability of the gate driving device may be improved

### BRIEF DESCRIPTION OF THE DRAWINGS

FIG. 1 is a schematic diagram of a gate driving circuit according to an embodiment of the disclosure.

FIG. 2 is a schematic diagram of a gate driving circuit according to an embodiment of the disclosure.

FIG. 3 is a timing diagram according to an embodiment of the disclosure.

FIG. 4 is a timing diagram according to an embodiment of the disclosure.

### DETAILED DESCRIPTION OF DISCLOSED EMBODIMENTS

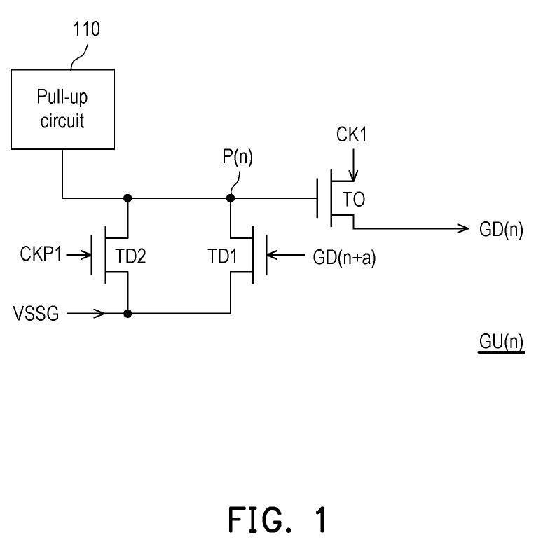

Referring to FIG. 1, FIG. 1 is a schematic diagram of a gate driving circuit according to an embodiment of the disclosure. In this embodiment, a gate driving circuit GU(n) may be a gate driving unit in a gate driving device. The gate driving device may be applied to a light detection device, a touch device, a radio frequency device, or a display device. The gate driving circuit GU(n) includes an output transistor TO, a first discharge transistor TD1, and a second discharge transistor TD2. A first terminal of the output transistor TO receives an operating clock CK1. A control terminal of the output transistor TO is connected to a control node P(n). The output transistor TO generates an n-th stage gate driving signal GD(n) according to a voltage value of the control node P(n) and the operating clock CK1. The output transistor TO outputs the n-th stage gate driving signal GD(n) through a second terminal of the output transistor TO. In this embodiment, n is a positive integer.

The first discharge transistor TD1 is connected to the control node P(n). The first discharge transistor TD1 discharges the voltage value located at the control node P(n) in a first time interval of the gate driving circuit GU(n). The second discharge transistor TD2 is connected to the control node P(n). The second discharge transistor TD2 discharges the voltage value located at the control node P(n) in a second time interval of the gate driving circuit GU(n). The second time interval is different from the first time interval. In other words, the first discharge transistor TD1 and the second discharge transistor TD2 respectively discharge the voltage value located at the control node P(n) in different time intervals. Therefore, the voltage value located at the control node P(n) is not susceptible to interference of noise. In this way, a risk of an abnormal output of the gate driving circuit GU(n) is reduced. Operating stability of the gate driving device may be improved.

A first terminal of the first discharge transistor TD1 is connected to the control node P(n). A second terminal of the first discharge transistor TD1 is connected to a first reference voltage VSSG. A control terminal of the first discharge transistor TD1 receives an (n+a)th stage gate driving signal GD(n+a), where “a” is a positive integer. For example, a may be equal to “1”, but the disclosure is not limited thereto. In this embodiment, the (n+a)th stage gate driving signal GD(n+a) may be a gate driving signal from other gate driving circuits. A first terminal of the second discharge transistor TD2 is connected to the control node P(n). A second terminal of the second discharge transistor TD2 is connected to the first reference voltage VSSG. A control terminal of the second discharge transistor TD2 receives a discharge control clock CKP1.

A pulse wave of the (n+a)th stage gate driving signal GD(n+a) is generated in the first time interval of the gate driving circuit GU(n). Therefore, in the first time interval of the gate driving circuit GU(n), the first discharge transistor TD1 pulls down the voltage value located at the control node P(n) by using the first reference voltage VSSG in response to the pulse wave of the (n+a)th stage gate driving signal GD(n+a). A pulse wave of the discharge control clock CKP1 is generated in the second time interval of the gate driving circuit GU(n). Therefore, in the second time interval of the gate driving circuit GU(n), the second discharge transistor TD2 pulls down the voltage value located at the control node P(n) by using the first reference voltage VSSG in response to the pulse wave of the discharge control clock CKP1.

The gate driving circuit GU(n) further includes a pull-up circuit 110. The pull-up circuit 110 is connected to the control node P(n). The pull-up circuit 110 raises the voltage value located at the control node P(n). For example, the pull-up circuit 110 raises the voltage value located at the control node P(n) according to an (n-a)th stage gate driving signal. For example, the pull-up circuit 110 raises the voltage value located at the control node P(n) according to an initial signal (e.g., an initial signal STV).

The output transistor TO, the first discharge transistor TD1, and the second discharge transistor TD2 may be implemented by any form of an N-type transistor. For example, the output transistor TO, the first discharge transistor TD1, and the second discharge transistor TD2 may respectively be implemented by an N-type thin film transistor (TFT). For example, the output transistor TO, the first discharge transistor TD1, and the second discharge transistor TD2 may respectively be implemented by an N-type LTPS TFT but, the disclosure is not limited thereto.

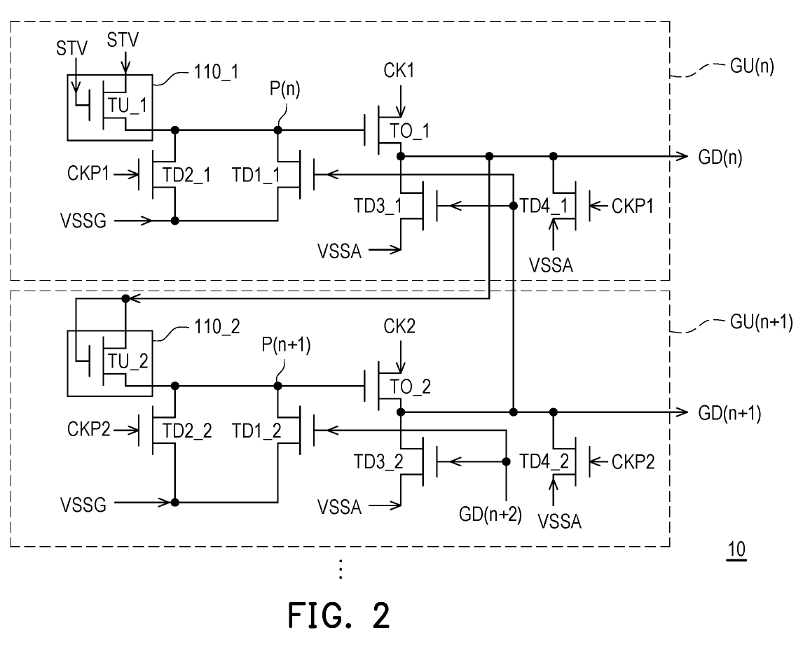

Referring to FIG. 2, FIG. 2 is a schematic diagram of a gate driving circuit according to an embodiment of the disclosure. FIG. 2 shows gate driving circuits GU(n) and GU(n+1). Therefore, the gate driving circuit GU(n) may be the first stage gate driving circuit. The gate driving circuit GU(n+1) may be the second stage gate driving circuit. The gate driving circuit GU(n) includes an output transistor TO_1, a first discharge transistor TD1_1, a second discharge transistor TD2_1, and a pull-up circuit 110_1. Implementations of the output transistor TO_1, the first discharge transistor TD1_1, the second discharge transistor TD2_1, and the pull-up circuit 110_1 are similar to implementations of the output transistor TO, the first discharge transistor TD1, and the second discharge transistor TD2 shown in FIG. 1. In this embodiment, the gate driving circuit GU(n+1) includes an output transistor TO_2, a first discharge transistor TD1_2, a second discharge transistor TD2_2, and a pull-up circuit 110_2. Implementations of the output transistor TO_2, the first discharge transistor TD1_2, and the second discharge transistor TD2_2 are similar to the implementations of the output transistor TO, the first discharge transistor TD1, and the second discharge transistor TD2 shown in FIG. 1.

The pull-up circuit 110_1 includes a pull-up transistor TU_1. A first terminal of the pull-up transistor TU_1 and a control terminal of the pull-up transistor TU_1 receive the initial signal STV. A second terminal of the pull-up transistor TU_1 is connected to the control node P(n). The pull-up transistor TU_1 is turned on according to a pulse wave of the initial signal STV to raise the voltage value located at the control node P(n).

The pull-up circuit 110_2 includes a pull-up transistor TU_2. A first terminal of the pull-up transistor TU_2 and a control terminal of the pull-up transistor TU_2 receive the n-th stage gate driving signal GD(n). A second terminal of the pull-up transistor TU_2 is connected to a control node P(n+1). The pull-up transistor TU_2 is turned on according to a pulse wave of the n-th stage gate driving signal GD(n) to raise a voltage value located at the control node P(n+1).

The gate driving circuit GU(n) further includes a third discharge transistor TD3_1 and a fourth discharge transistor TD4_1. The third discharge transistor TD3_1 is connected to a second terminal of the output transistor TO_1. The third discharge transistor TD3_1 discharges a voltage value located at the second terminal of the output transistor TO_1 in the first time interval of the gate driving circuit GU(n). The fourth discharge transistor TD4_1 is connected to the second terminal of the output transistor TO_1. The fourth discharge transistor TD4_1 discharges the voltage value located at the second terminal of the output transistor TO_1 in the second time interval of the gate driving circuit GU(n).

In this embodiment, a first terminal of the third discharge transistor TD3_1 is connected to the second terminal of the output transistor TO_1. A second terminal of the third discharge transistor TD3_1 is connected to a second reference voltage VSSA. A control terminal of the third discharge transistor TD3_1 receives an (n+1)th stage gate driving signal GD(n+1).

A first terminal of the fourth discharge transistor TD4_1 is connected to the second terminal of the output transistor TO_1. A second terminal of the fourth discharge transistor TD4_1 is connected to the second reference voltage VSSA. A control terminal of the fourth discharge transistor TD4_1 receives the discharge control clock CKP1.

A pulse wave of the (n+1)th stage gate driving signal GD(n+1) is generated in the first time interval of the gate driving circuit GU (n). Therefore, in the first time interval of the gate driving circuit GU(n), the third discharge transistor TD3_1 pulls down the voltage value located at the second terminal of the output transistor TO_1 in response to the pulse wave of the (n+1)th stage gate driving signal GD(n+1). The pulse wave of the discharge control clock CKP1 is generated in the second time interval of the gate driving circuit GU(n). Therefore, in the second time interval of the gate driving circuit GU(n), the fourth discharge transistor TD4_1 pulls down the voltage value located at the second terminal of the output transistor TO_1 by using the second reference voltage VSSA in response to the pulse wave of the discharge control clock CKP1.

The gate driving circuit GU(n+1) further includes a third discharge transistor TD3_2 and a fourth discharge transistor TD4_2. The operations of the third discharge transistor TD3_2 and the fourth discharge transistor TD4_2 is similar to the operations of the third discharge transistor TD3_1 and the fourth discharge transistor TD4_1 of the gate driving circuit GU(n).

A control terminal of the third discharge transistor TD3_2 receives an (n+2)th stage gate driving signal GD(n+2) provided by other gate driving circuits. A control terminal of the fourth discharge transistor TD4_2 receives a discharge control clock CKP2.

The output transistors TO_1 and TO_2, the first discharge transistors TD1_1 and TD1_2, the second discharge transistors TD2_1 and TD2_2, the third discharge transistors TD3_1 and TD3_2, the fourth discharge transistors TD4_1 and TD4_2, and the pull-up transistors TU_1 and TU_2 may respectively be implemented by N-type transistor. Voltage values of the reference voltages VSSG and VSSA may be lower than or equal to 0 volts respectively.

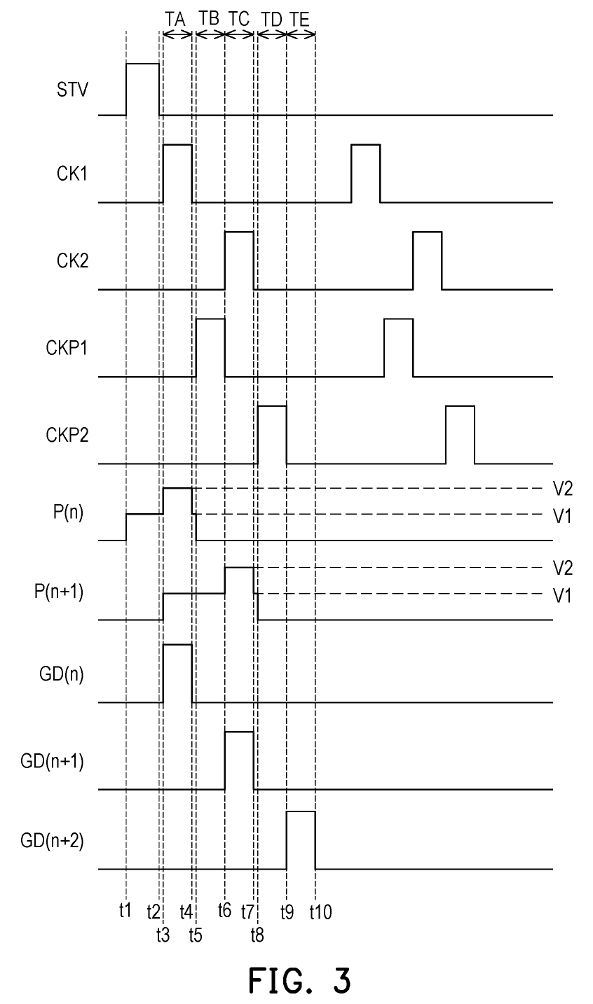

Referring to FIGS. 2 and 3, FIG. 3 shows a partial timing diagram in a single frame period. In this embodiment, between a time point t1 and a time point t2, the initial signal STV has the pulse wave (i.e., a positive pulse wave). Therefore, the pull-up transistor TU_1 is turned on by using the pulse wave of the initial signal STV and raises the voltage value located at the control node P(n) to a voltage level V1. The output transistor TO_1 is turned on. After the time point t2, the pull-up transistor TU_1 is turned off. The control node P(n) is floated.

In a time interval TA between a time point t3 and a time point t4 (a third time interval of the gate driving circuit GU(n)), a pulse wave of the operating clock CK1 is generated. Therefore, in the time interval TA, the output transistor TO_1 further raises the voltage value located at the control node P(n) to a higher voltage level V2 by using capacitor coupling between the second terminal and a control terminal of the output transistor TO_1. In the time interval TA, the n-th stage gate driving signal GD(n) has the pulse wave.

In the time interval TA, the pull-up transistor TU_2 is turned on according to the pulse wave of the n-th stage gate driving signal GD(n) and raises the voltage value located at the control node P(n+1) to the voltage level V1 by using the pulse wave of the n-th stage gate driving signal GD(n). After the time point t4, the pull-up transistor TU_2 is turned off. Therefore, the control node P(n+1) is floated. In a time interval TB between a time point t5 and a time point t6 (the second time interval of the gate driving circuit GU(n)), the discharge control clock CKP1 has the pulse wave. The second discharge transistor TD2_1 and the fourth discharge transistor TD4_1 are turned on according to the pulse wave of the discharge control clock CKP1. Therefore, in the time interval TB (i.e., the second time interval of the gate driving circuit GU(n)), the voltage value located at the control node P(n) and the voltage value located at the n-th stage gate driving signal GD(n) are pulled down to a low potential.

In a time interval TC between the time point t6 and a time point t7 (the first time interval of the gate driving circuit GU(n) or the third time interval of the gate driving circuit GU(n+1)), a pulse wave of an operating clock CK2 is generated. Therefore, in the time interval TC, the output transistor TO_2 further raises the voltage value located at the control node P(n+1) from the voltage level V1 to the higher voltage level V2 by using capacitor coupling between the second terminal of the output transistor TO_2 and a control terminal of the output transistor TO_2. Therefore, in the time interval TC, the output transistor TO_2 may ensure that it is in the turned-on state. In the time interval TC (the first time interval of the gate driving circuit GU(n)), the (n+1)th stage gate driving signal GD(n+1) has the pulse wave.

In the time interval TC, the first discharge transistor TD1_1 and the third discharge transistor TD3_1 are turned on according to the pulse wave of the (n+1)th stage gate driving signal GD(n+1). Therefore, the voltage value located at the control node P(n) and the voltage value located at the n-th stage gate driving signal GD(n) are pulled down to the low potential.

In a time interval TD between a time point t8 and a time point t9, the discharge control clock CKP2 has the pulse wave. The second discharge transistor TD2_2 and the fourth discharge transistor TD4_2 are turned on according to the pulse wave of the discharge control clock CKP2. Therefore, the voltage value located at the control node P(n+1) and the voltage value located at the (n+1)th stage gate driving signal GD(n+1) are pulled down to the low potential.

In a time interval TE between the time point t9 and a time point t10 (the first time interval of the gate driving circuit GU(n+1)), the first discharge transistor TD1_2 and the third discharge transistor TD3_2 are turned on. Therefore, the voltage value located at the control node P(n+1) and the voltage value located at the (n+1)th gate driving signal GD(n+1) are pulled down to the low potential.

In the single frame period, the discharge control clock CKP1 has multiple pulse waves. Therefore, in the single frame period, the second discharge transistor TD2_1 and the fourth discharge transistor TD4_1 may perform the discharge operation multiple times. In the single frame period, the discharge control clock CKP2 has multiple pulse waves. Therefore, in the single frame period, the second discharge transistor TD2_2 and the fourth discharge transistor TD4_2 may also perform the discharge operation multiple times. The time interval between the pulse waves of the discharge control clock CKP1 is the same as the time interval between the pulse waves of the operating clock CK1. The discharge control clock CKP1 lags behind the operating clock CK1 by a fixed time length. In some embodiments, the time interval between the pulse waves of the discharge control clock CKP1 is greater than the time interval between the pulse waves of the operating clock CK1. For example, after multiple time intervals TA, a single pulse wave of the discharge control clock CKP1 is generated in the time interval TB.

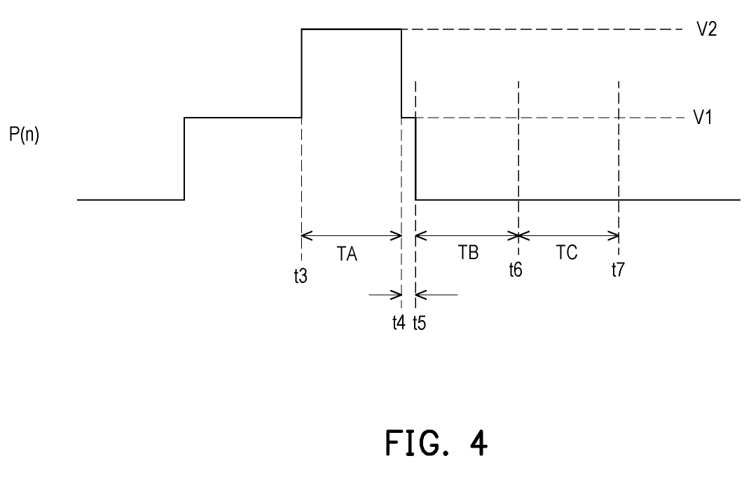

Referring to FIGS. 2, 3, and 4, FIG. 4 is a timing diagram according to an embodiment of the disclosure. FIG. 4 shows a timing diagram of a voltage located at the control node P(n). In this embodiment, in the time interval TB between the time interval TA and the time interval TC, the second discharge transistor TD2_1 performs the discharge operation on the voltage value located at the control node P(n). Therefore, after the time interval TA, a time length TF at which the voltage value located at the control node P(n) remains at the voltage level V1 is significantly shortened. That is, the time length TF from the time point t4 to the time point t5 is significantly shortened. Generally speaking, the operating clock CK1 of the time length may have noise (e.g., unexpected pulse waves). In the time length TF, the output transistor TO_1 is still turned on. Therefore, the n-th stage gate driving signal GD(n) also has the similar noise. It should be noted that in this embodiment, the time length TF is significantly shortened. The time that the output transistor TO_1 is turned on after the time interval TA is also shortened to isolate the noise of the operating clock CK1. Therefore, a risk that the n-th stage gate driving signal GD(n) has the similar noise is reduced.

Based on the above, the gate driving circuit includes the first discharge transistor and the second discharge transistor. The first discharge transistor discharges the voltage value located at the control node in the first time interval. The second discharge transistor discharges the voltage value located at the control node in the second time interval. The second time interval is different from the first time interval. Therefore, the voltage value located at the control node is not susceptible to the interference noise. In this way, the risk of the abnormal output of the gate driving circuit is reduced. The operating stability of the gate driving device may be improved.

What is claimed is:

1. A gate driving circuit, comprising:
an output transistor, wherein a first terminal of the output transistor receives an operating clock, and a control terminal of the output transistor is connected to a control node, wherein the output transistor generates an n-th stage gate driving signal according to a voltage value of the control node and the operating clock, and outputs the n-th stage gate driving signal through a second terminal of the output transistor;
a first discharge transistor connected to the control node and configured to discharge the voltage value located at the control node in a first time interval; and
a second discharge transistor connected to the control node and configured to discharge the voltage value located at the control node in a second time interval,
wherein the second time interval is different from the first time interval,
where n is a positive integer.

2. The gate driving circuit according to claim 1, wherein
a first terminal of the second discharge transistor is connected to the control node,
a second terminal of the second discharge transistor is connected to a first reference voltage, and
a control terminal of the second discharge transistor receives a discharge control clock.

3. The gate driving circuit according to claim 2, wherein in the second time interval, the second discharge transistor is turned on according to a pulse wave of the discharge control clock, and pulls down the voltage value located at the control node by using the first reference voltage.

4. The gate driving circuit according to claim 2, wherein
a first terminal of the first discharge transistor is connected to the control node,
a second terminal of the first discharge transistor is connected to the first reference voltage,
a control terminal of the first discharge transistor receives an (n+a)th stage gate driving signal, and
a is a positive integer.

5. The gate driving circuit according to claim 4, wherein in the first time interval, the first discharge transistor is turned on according to a pulse wave of the (n+a)th stage gate driving signal, and pulls down the voltage value located at the control node by using the first reference voltage.

6. The gate driving circuit according to claim 4, wherein
a pulse wave of the (n+a)th stage gate driving signal is generated in the first time interval, and
a pulse wave of the discharge control clock is generated in the second time interval.

7. The gate driving circuit according to claim 4, wherein the (n+a)th stage gate driving signal comes from an (n+a)th stage gate driving circuit.

8. The gate driving circuit according to claim 4, wherein
a pulse wave of the operating clock is generated in a third time interval, and
after the third time intervals, a single pulse wave of the discharge control clock is generated in the second time interval.

9. The gate driving circuit according to claim 1, wherein
a pulse wave of the operating clock is generated in a third time interval, and
the second time interval is later than the third time interval and earlier than the first time interval.

10. The gate driving circuit according to claim 1, further comprising:
a third discharge transistor connected to the second terminal of the output transistor and configured to discharge the voltage value located at the second terminal of the output transistor in the first time interval.

11. The gate driving circuit according to claim 10, wherein
a first terminal of the third discharge transistor is connected to the second terminal of the output transistor,
a second terminal of the third discharge transistor is connected to a second reference voltage,
a control terminal of the third discharge transistor receives an (n+a)th stage gate driving signal, and
a is a positive integer.

12. The gate driving circuit according to claim 11, wherein in the first time interval, the third discharge transistor is turned on according to a pulse wave of the (n+a)th stage gate driving signal, and pulls down the second terminal of the output transistor by using the second reference voltage.

13. The gate driving circuit according to claim 10, further comprising:
a fourth discharge transistor connected to the second terminal of the output transistor and configured to discharge the voltage value located at the second terminal of the output transistor in the second time interval.

14. The gate driving circuit according to claim 13, wherein
a first terminal of the fourth discharge transistor is connected to the second terminal of the output transistor,
a second terminal of the fourth discharge transistor is connected to a second reference voltage, and
a control terminal of the fourth discharge transistor receives a discharge control clock.

15. The gate driving circuit according to claim 14, wherein in the second time interval, the third discharge transistor is turned on according to a pulse wave of the discharge control clock, and pulls down the voltage value located at the second terminal of the output transistor by using the second reference voltage.

16. The gate driving circuit according to claim 1, further comprising:
a pull-up circuit connected to the control node and configured to raise the voltage value located at the control node to a first voltage level according to one of an (n-a)th stage gate driving signal and an initial signal,
wherein a is a positive integer.

17. The gate driving circuit according to claim 16, wherein in a period when the voltage value located at the control node is at the first voltage level, and the control node is floated, when a pulse wave of the operating clock is generated, the voltage value located at the control node is raised from the first voltage level to a second voltage level.

18. The gate driving circuit according to claim 16, wherein the pull-up circuit comprises:
a pull-up transistor, wherein a first terminal of the pull-up transistor and a control terminal of the pull-up transistor receive one of the (n-a)th stage gate driving signal and the initial signal, and a second terminal of the pull-up transistor is connected to the control node.

19. The gate driving circuit according to claim 16, wherein the pull-up circuit raises the voltage value located at the control node to the first voltage level according to a pulse wave of one of the (n-a)th stage gate driving signal and the initial signal.

20. The gate driving circuit according to claim 16, wherein the pull-up circuit is turned off to float the control node.
